(19) United States
(12) Patent Application Publication
(10) Pub. No.: US 2010/0163834 A1
(43) Pub. Date: Jul. 1, 2010

(54) CONTACT STRUCTURE, METHOD OF MANUFACTURING THE SAME, PHASE CHANGEABLE MEMORY DEVICE HAVING THE SAME, AND METHOD OF MANUFACTURING PHASE CHANGEABLE MEMORY DEVICE

(76) Inventor: Heon Yong CHANG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/494,388

(22) Filed: Jun. 30, 2009

(30) Foreign Application Priority Data
Dec. 29, 2008 (KR) 10-2008-0135498

(51) Int. Cl. H01L 45/00; H01L 23/522; H01L 21/28

(52) U.S. Cl. 257/4; 257/773; 438/653; 257/E23.145; 257/E21.158; 257/E45.002

(57) ABSTRACT

A contact structure, a method of manufacturing the same, a phase-changeable memory device having the same, and a method of manufacturing the phase-changeable memory device are described. The phase-changeable memory device includes: an upper electrode, a bit line, and a bit line contact unit. The upper electrode is on a semiconductor substrate having a phase-change pattern. The bit line is on the upper electrode. The bit line contact unit is interposed between the upper electrode and the bit line and electrically couples together the upper electrode to the bit line. The bit line contact unit includes a main conductive layer, a first and second barrier film. The first barrier film surrounds a bottom portion and a side portion of the main conductive layer. The second barrier film is on the main conductive layer.

### CROSS-REFERENCES TO RELATED PATENT APPLICATION

The present application claims priority under 35 U.S.C 119(a) to Korean Application No. 10-2008-0135498, filed on Dec. 29, 2008, in the Korean Intellectual Property Office, which is incorporated herein by reference in its entirety as set forth in full.

### BACKGROUND

1. Technical Field

The present invention relates to a semiconductor apparatus and a method for manufacturing the same and, more particularly, to a contact structure, a method of manufacturing the same, a phase changeable memory device having the same, and a method of manufacturing the phase changeable memory device.

2. Related Art

Next-generation memory devices that are nonvolatile and do not need to be refreshed are being researched at a request for low power consumption of a memory device. A phase-change random access memory (hereinafter, referred to as ‘PRAM’), which is one of the next-generation memory devices, stores binary information by using characteristics of a phase-changeable material, i.e., GeSbTe that is changed into a crystalline state and an amorphous state by partial generation of heat, which is caused by an electrical pulse.

That is, the phase of the PRAM is changed between the amorphous state and the crystalline state by current applied to the phase-changeable material, i.e., Joule's heat. At this time, since the phase-changeable material in the crystalline state has low resistance and the phase-changeable material in the amorphous state has high resistance, the crystalline state can be defined as set or a logical level of 0 and the amorphous state can be defined as reset or a logical level of 1.

As a result, the phase-changeable memory device can store on/off digital data by using the phase change of the phase-changeable material and read digital data by using the on/off digital data.

Herein, the state of the phase-changeable material is changed by current applied to the phase-changeable material and the current is formed by an electric field that is formed between word lines and bit lines. Herein, the word line may be a junction region that contacts with a switching element in the phase-changeable memory device and the bit line may be a metallic wire that contacts with an upper electrode of the phase-changeable memory device.

More specifically, the bit line is connected to the upper electrode that is electrically coupled to the phase-changeable material via a bit line contact unit. At present, since a bit line contact unit of a high-integration phase-changeable memory device has a high aspect ratio, a cavity that is referred to as a seam may be provided. Moreover, in order to form a follow-up bit line, the bit line contact unit is flattened by chemical and mechanical grinding, etc.

Meanwhile, at present, the bit line of the phase-changeable memory device is formed by a damascene technique so as to be fabricated uniformly while being electrically coupled to the bit line contact unit.

However, as the integration density of the phase-changeable memory device increases, a gap between the bit line contact units also becomes narrow. As described above, since the aspect ratio of the bit line contact unit is also high, an upper region of the bit line contact unit inclines to the adjacent bit line contact unit. As a result, a problem such as a bridge, etc. may occur.

At present, a method of removing the bridge by excessively grinding an upper surface of the bit line contact unit has been proposed.

However, as such, since the bit line contact unit can include the seam therein, the seam may be exposed during the excessive grinding. As such, when the seam is exposed, the follow-up bit line and bit line contact unit cannot stably contact with each other and the bit line may be uneven due to the seam. As a result, contact resistance increases, thereby deteriorating electrical characteristics.

### SUMMARY

A contact structure and a method of manufacturing the same that can reduce contact resistance are disclosed herein.

A phase-changeable memory device and a method of manufacturing the same that can stably contact a bit line and a bit line contact with each other are also disclosed herein.

In a first embodiment, a contact structure provided in an interlayer insulating layer in order to connect an upper portion of the interlayer insulating layer and a lower conductive layer includes: a main conductive layer; a first barrier film configured to surround a bottom portion and a side wall portion of the main conductive layer; and a second barrier film configured to be formed on a top portion of the main conductive layer.

Further, in a second embodiment, a method of manufacturing a contact structure includes: providing a semiconductor substrate with a conductive layer; forming an insulating layer on the semiconductor substrate; forming a contact hole by etching the insulating layer so as to expose the conductive layer; forming a first barrier film on a bottom portion and an inner wall portion of the contact hole; forming a main conductive layer so as to bury the contact hole; chemically and mechanically grinding the main conductive layer and the first barrier film so as to expose the surface of the insulating layer; and forming a second barrier film on the main conductive layer.

In a third embodiment, a phase-changeable memory device includes: an upper electrode configured to be formed on a semiconductor substrate having a phase-change pattern; a bit line configured to be formed on the upper electrode; and a bit line contact unit configured to be interposed between the upper electrode and the bit line and electrically connect the upper electrode and the bit line to each other, wherein the bit line contact unit includes a main conductive layer, a first barrier film configured to surround a bottom portion and a side portion of the main conductive layer, and a second barrier film configured to be formed on the main conductive layer.

In a fourth embodiment, a method of manufacturing a phase-changeable memory device includes: forming an upper electrode on a top portion of a semiconductor substrate including a phase-change pattern; forming an interlayer insulating layer on the top portion of the semiconductor substrate result where the upper electrode is formed; forming a via-hole by etching the interlayer insulating layer so as to expose a top surface of the upper electrode; forming a first barrier film on a bottom portion and a side wall portion of the via-hole; forming a main conductive layer so as to bury the via-hole; flattening the main conductive layer and the first barrier film so as to expose the interlayer insulating layer; forming a bit line contact unit by forming a second barrier film on the main conductive layer; and forming a bit line on the bit line contact unit.

According to embodiments of the present invention, a bit line contact unit that electrically connect an upper electrode of a phase-changeable memory device and a bit line with each other is constituted by a main conductive layer, a first barrier layer configured to surround a bottom portion and a side wall portion thereof, and a second barrier layer configured to cover a top portion thereof. As a result, since exposure of the main conductive layer having a seam is interrupted by the second barrier layer, the bit line contact unit and the bit line can stably contact with each other.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a cross-sectional view of an exemplary phase-changeable memory device according to a first embodiment;

FIGS. 2 to 6 are cross-sectional views of an exemplary is phase-changeable memory device according to a second embodiment; and

FIG. 7 is a cross-sectional view of an exemplary phase-changeable memory device according to a third embodiment.

### DETAILED DESCRIPTION

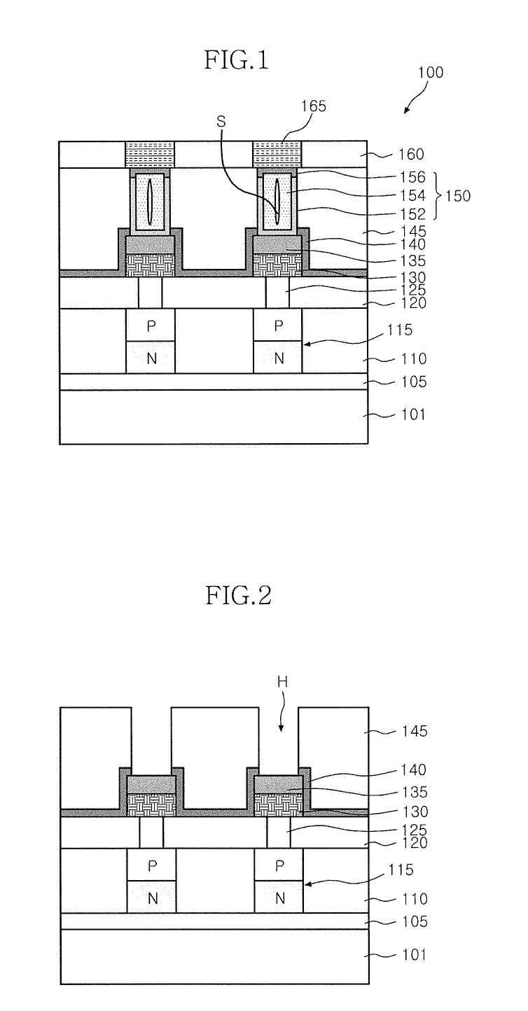

Referring to FIG. 1, a phase-changeable memory device 100 can be configured to include a semiconductor substrate 101, a switching element 115, a lower electrode 125, a phase-changeable material layer 130, an upper electrode 135, a bit line contact unit 150, and a bit line 165. It is understood herein that the drawings are not necessarily to scale and in some instances proportions may have been exaggerated in order to more clearly depict certain features of the invention.

The semiconductor substrate 101 can be configured to include a word line 105 having a junction region form. The semiconductor substrate 101 may be a silicon (Si) substrate, a germanium (Ge) substrate, or a compound substrate and may include a well for electrical characteristics. In addition, the word line 105 may be configured of an n-type impurity region.

The switching element 115 can be electrically coupled to the word line 105 along an upper part of the semiconductor substrate 101. The switching element 115 may be a PN diode 115. The switching element 115 is electrically insulated from another adjacent switching element 115 by a first interlayer insulating layer 110. Herein, although not shown in the figure, an ohmic contact layer (not shown) may be formed on the surface of the switching element 115.

The lower electrode 125 is electrically coupled to the switching element 115. The lower electrode 125 is used as a medium for heating the phase-changeable material layer 130, and can have a line width smaller than the switching element 115. The lower electrode 125 can be made of a conductive material having high specific resistance such as a titanium nitride film (TiN), a titanium aluminum nitride film (TiAlN), a titanium tungsten film (TiW), a polysilicon film (Poly-Si), or a silicon germanium film (SiGe) so as to provide a large amount of heat to the phase-changeable material layer 130. The lower electrode 125 can be electrically insulated away from another adjacent lower electrode 125 by a second interlayer insulating layer 120. The second interlayer insulating layer 120 may adopt an insulating film having a high heat-resistance, i.e., a silicon nitride film (Si₃N₄), so as to protect against heat generated from the lower electrode 125 from being transferred.

The phase-changeable material layer 130 is formed in an upper part of the second interlayer insulating layer 120 in contact with the lower electrode 125. The phase-changeable material layer 130 may have a line width larger than the lower electrode 125. The phase of the phase-changeable material layer 130 is varied by the heat transferred by the lower electrode 125. The phase-changeable material layer 130 may adopt various types of GST compounds such as a GST compound containing germanium-antimony-tellurium, a GST compound doped with carbon, nitrogen, oxygen/or metal, etc.

The upper electrode 135 is formed in the upper part of the phase-changeable material layer 130 in the same form as the phase-changeable material layer 130. The upper electrode 135 may be a metallic film or a conductive nitrogen film. A laminated structure that is constituted by the phase-changeable material layer 130 and the upper electrode 135 may be surrounded by a protection film 140. The protection film 140 can be provided to protect against components constituting the phase-changeable material layer 130 from being diffused when the crystalline state phase of the phase-changeable material layer 130 is transitioned.

The bit line contact unit 150 is provided to electrically connect the upper electrode 135 and the bit line 165 with each other. The bit line contact unit 150 can be configured to include a first barrier film 152, a main conductive layer 154, and a second barrier film 156. The first barrier film 152 is configured to surround a bottom portion and a side wall portion of the main conductive layer 154. In other words, the first barrier film 152, which preferably has a cup shape, is configured to house the main conductive layer 154. At this time, the first barrier film 152 that is positioned in the side wall portion of the main conductive layer 154 has a lower height than the main conductive layer 154 and the second barrier film 156 is configured to surround a top portion of the main conductive layer and the side wall of the exposed side wall portion of the main conductive layer 154. That is, the second barrier film 156 has a cap shape. Therefore, even though a seam s may be formed in the main conductive layer 154, the main conductive layer 154 is prevented from being exposed by the second barrier film 156. Herein, the first and second barrier films 152 and 156 may be made of the same material, i.e., a metallic nitride film such as a titanium nitride film, a titanium aluminum nitride film, or a tungsten nitride film. Further, the second barrier film 156 may be made of a material having more excellent conductive characteristics than the first barrier film 152. The main conductive layer 154 may adopt a material that has etching selectivity different from the first and second barrier films 156 and excellent burying characteristics, for example, a tungsten metal film.

The bit line contact unit 150, the upper electrode 135, and the phase-changeable material layer 130 that are electrically coupled to each other are electrically insulated from another adjacent bit line contact unit 150, upper electrode 135, and phase-changeable material layer 130 by using a third interlayer insulating layer 145. In addition, a top surface of the third interlayer insulating layer 145 and a top surface of the second barrier film 156 are preferably positioned along a straight line without a step to provide an even surface, i.e., level with respect to each other. That is the top surface of the third interlayer insulating layer 145 and the top surface of the second barrier film 156 are preferably positioned level to each other.

The bit line 165 is formed on the bit line contact unit 150 so as to be electrically coupled to the bit line contact unit 150. The bit line 165 may be formed by a conductive layer having excellent electrical characteristics. The bit line 165 is electrically insulated from another adjacent bit line 165 by using a fourth interlayer insulating layer 160.

The phase-changeable memory device having the above-mentioned structure can be configured to include a bit line contact unit 150 having a cap-shaped second barrier film 156 that covers the top portion of the main conductive layer 154. As a result, when a grinding process for removing a bridge is performed, the seam in the main conductive layer 154 is not exposed, such that the bit line 165 and the bit line contact unit 150 can stably contact with each other.

A method of manufacturing the phase-changeable memory device will be described in detail with reference to FIGS. 2 to 5.

Referring to FIG. 2, the word line 105 is formed on the semiconductor substrate 101 by injecting n-type impurities. The first interlayer insulating layer 110 having a predetermined thickness is formed on the semiconductor substrate 101 and the switching element 115, i.e., the PN diode is formed so as to electrically couple to the word line 105. The PN diode can be acquired by forming a contact hole (not shown) by etching the first interlayer insulating layer 110 so as to expose the word line 105, forming an n-type selective epitaxial growth (SEG) film so as to bury the contact hole, and injecting p-type impurities onto the n-type SEG film.

The second interlayer insulating layer 120 is deposited on the first interlayer insulating layer 110 in which the switching element 115 is formed. Next, after a contact hole (not shown) is formed to expose a top surface of the switching element 115, the lower electrode 125 is formed by burying a conductive layer having high specific resistance.

After the phase-changeable material layer 130 and the upper electrode 135 are sequentially laminated on the second interlayer insulating layer 120, the phase-changeable material layer 130 and the upper electrode 135 are etched in a pattern shape so as to separate the phase-changeable material layer 130 and the upper electrode 135 for each unit cell.

The protection film 140 is formed on the second interlayer insulating layer 120 so as to cover the phase-changeable material layer 130 and the upper electrode 135. The protection film 140 may adopt a silicon nitride film or a silicon oxide film.

The third interlayer insulating layer 145 is deposited on the protection film 140. Next, a via-hole H is formed by etching the third interlayer insulating layer 145 and the protection film 140 so as to expose the surface of the upper electrode 135.

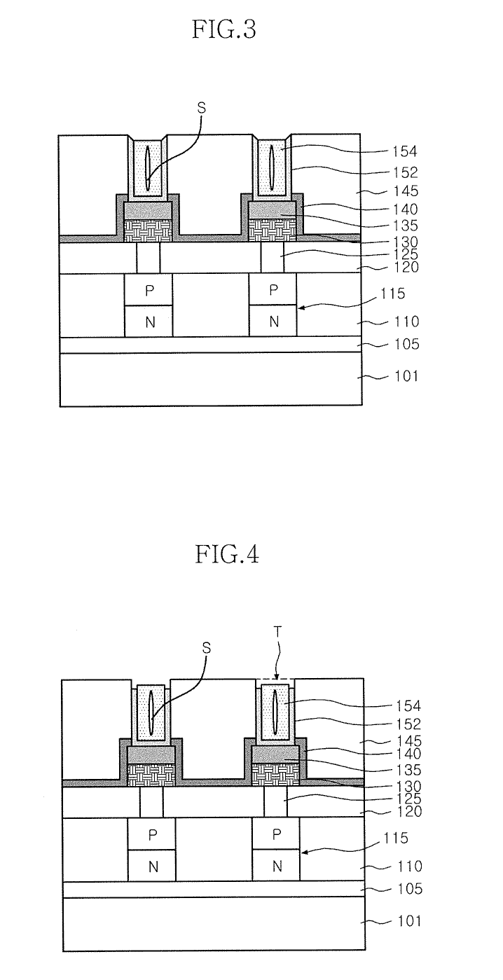

Referring to FIG. 3, a first barrier film 151 is deposited on the surface of the via-hole H and the main conductive layer 154 is formed on the first barrier film 151 so as to charge the via-hole H. At this time, the first barrier film 151 may adopt the metallic nitride film such as the titanium nitride film, the titanium aluminum nitride film, or the tungsten nitride film. The main conductive layer 154 may adopt a tungsten film having an excellent burying characteristic. Moreover, the seam ‘s’ may be generated in the main conductive layer 154 charged in the via-hole H due to a high aspect ratio of the via-hole H.

Next, the main conductive layer 154 and the first barrier film 151 are flattened so as to expose the surface of the third interlayer insulating layer 145. At this time, a flattening (planarizating) method may adopt a chemical and mechanical grinding method. In this step, excessive chemical and mechanical polishing(or grinding) is allowed to create perfect node separation. In addition, the excessive chemical and mechanical grinding process can be performed with intensity of a level not to expose the seam.

Moreover, since the main conductive layer 154 is mostly removed during the excessive chemical and mechanical polishing(or grinding) process, the excessive chemical and mechanical grinding process can be performed by using the main conductive layer 154 as a polishing target. Therefore, when the excessive chemical and mechanical grinding is performed with respect to the main conductive layer 154, the main conductive layer 154 is substantially lower than the surface of the third interlayer insulating layer 145. As a result, the first barrier film 151 that is interposed between the main conductive layer 154 and the third interlayer insulating layer 145 has a top surface having a natural slope.

Next, as shown in FIG. 4, the exposed first barrier film 151 is selectively etched with a predetermined thickness. Preferably, the first barrier film 151 is etched with a predetermined thickness so that the height of the first barrier film 151 that is positioned on a side wall of the via-hole H is equal to or less than the height of the main conductive layer 154. In the embodiment, the first barrier film 151 is preferably etched to a thickness of about 500 to 1500 Å. Reference numeral 152 represents a first barrier film of which a predetermined portion is selectively etched. As a result, a stepped portion ‘T’ having a very shallow depth is formed between the third interlayer insulating layer 145 and the conductive members 152 and 154 that are buried in the via-hole H.

Referring to FIG. 5, a thin second barrier film 156 is formed on the third interlayer insulating layer 145 so as to sufficiently charge the stepped portion ‘T’. The second barrier film 156 may be made of the same material as or a different material from the first barrier film 156. Next, the second barrier film 156 is flattened so that the surface of the second barrier film 156 and the third interlayer insulating layer 145 may be formed on the straight line without having a step, i.e., level to each other. Since the second barrier film 156 is very thin, the flattening process may be an under chemical and mechanical grinding process that is performed with a little weak intensity. Therefore, the cap-shaped second barrier film 156 that covers the surface of the main conductive layer 154 is formed on the main conductive layer 154, such that the bit line contact unit 150 is formed. The semiconductor substrate result is flattened by forming the bit line contact unit 150.

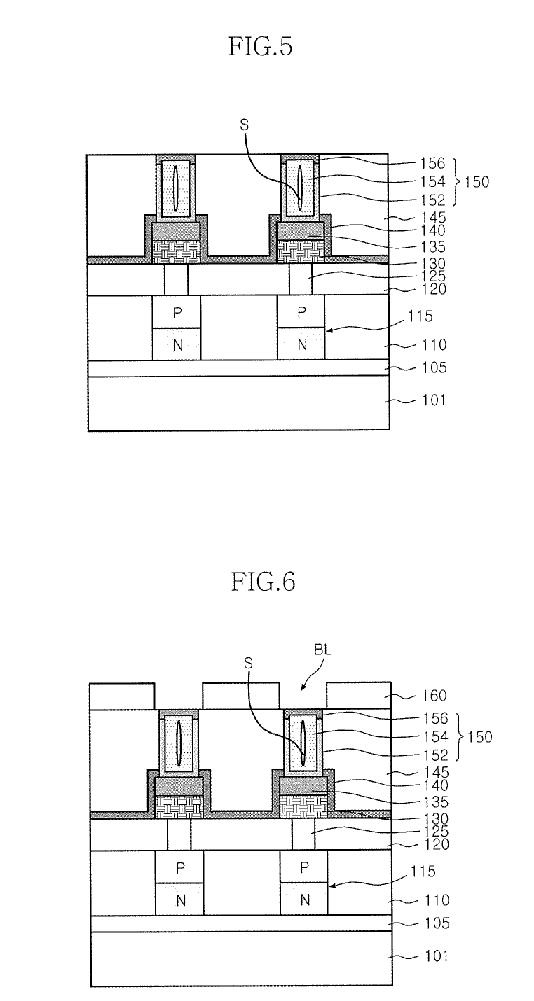

Next, referring to FIG. 6, a fourth interlayer insulating layer 160 is formed on the result of the semiconductor substrate 101 where the bit line contact unit 150 is formed. Next, a bit line expected region BL is defined by etching the fourth interlayer insulating layer 160 so as to expose the bit line contact unit 150.

Thereafter, after a conductive film is formed to charge the bit line expected region BL, the bit line 165 is formed depending on a damascene technique by polishing the conductive film so as to expose the fourth interlayer insulating layer 160.

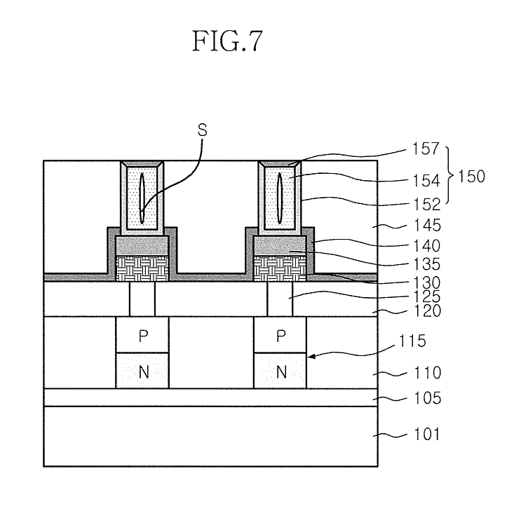

FIG. 7 is a cross-sectional view of a phase-changeable memory device according to a third embodiment.

In the above-mentioned embodiments, after the excessive chemical and mechanical polishing process with respect to the main conductive layer 154 and the first barrier film 152, the stepped portion ‘T’ which is a space where the second barrier film 156 will be formed is provided by selectively etching the first barrier film 152 (see FIG. 4).

However, in the embodiment, as shown in FIG. 7, a second barrier film 157 that covers the main conductive layer 154 with a thinner thickness may be formed by depositing the thin second barrier film 157 without selectively etching the first barrier film 152 and under-chemically and mechanically polishing the deposited second barrier film.

As described in detail above, a bit line contact unit 150 that electrically connects an upper electrode of a phase-changeable memory device and a bit line to each other includes a main conductive layer 154, a first barrier film 152 configured to surround a bottom portion and a side wall portion of the main conductive layer 154, and a second barrier film 156 or 157 configured to cover the first barrier film 152. As a result, since exposure of the main conductive layer 154 having a seam is interrupted by the second barrier film 156 or 157, the bit line contact unit 150 and the bit line 165 can stably contact with each other.

However, the present invention is not limited thereto.

In the embodiment, although a bit line contact structure of a phase-changeable memory device has been described as one example, the embodiment is not limited thereto and can be applied to all contact structures having a seam.

While certain embodiments have been described above, it will be understood to those skilled in the art that the embodiments described are by way of example only. Accordingly, the apparatus described herein should not be limited based on the described embodiments. Rather, the apparatus described herein should only be limited in light of the claims that follow when taken in conjunction with the above description and accompanying drawings.

What is claimed is:

1. A contact structure provided in an interlayer insulating layer in order to connect an upper portion of the interlayer insulating layer and a lower conductive layer, comprising:
a main conductive layer;
a first barrier film on a bottom portion and surrounding a portion of a side wall portion of the main conductive layer; and
a second barrier film on a top portion of the main conductive layer.

2. The contact structure of claim 1, wherein the surface of the second barrier film and the surface of the interlayer insulating layer are substantially level with respect to each other.

3. The contact structure of claim 1, wherein a top portion of the first barrier film along on the side wall portion of the main conductive layer is lower than a top surface of the main conductive layer.

4. The contact structure of claim 3, wherein both ends of the second barrier film extend downwards along to the side wall of the main conductive layer.

5. The contact structure of claim 1, wherein the first and second barrier films are made of the same material.

6. A method of manufacturing a contact structure, comprising:
providing a semiconductor substrate having a conductive layer;
forming an insulating layer on the semiconductor substrate;
forming a contact hole by etching into the insulating layer to expose the conductive layer;
forming a first barrier film on a bottom portion and an inner wall portion of the contact hole;
forming a main conductive layer to bury the contact hole;
chemically and mechanically grinding the main conductive layer and the first barrier film to expose the insulating layer; and
forming a second barrier film on the main conductive layer.

7. The method of claim 6, wherein the chemical and mechanical grinding step is excessively performed so that the main conductive layer is lower than the surface of the insulating layer.

8. The method of claim 7, wherein the forming the second barrier film includes:
depositing the second barrier film on the result; and
chemically and mechanically grinding the second barrier film and the insulating layer so that the second barrier film and the surface of the insulating layer are substantially level with each other.

9. A phase-changeable memory device, comprising:
an upper electrode on a semiconductor substrate;
a bit line configured to be formed on the upper electrode; and
a bit line contact unit interposed between the upper electrode and the bit line and electrically coupling together the upper electrode to the bit line,
wherein the bit line contact unit includes a main conductive layer, a first barrier film surrounding a bottom portion and a side portion of the main conductive layer, and a second barrier film on a top portion of the main conductive layer.

10. The phase-changeable memory device of claim 9, wherein interlayer insulating layers are further formed at both sides of the bit line contact unit.

11. The phase-changeable memory device of claim 10, wherein a top surface of the bit line contact unit and the surface of the interlayer insulating layer are substantially level with each other.

12. The phase-changeable memory device of claim 9, wherein the first barrier film that is formed on a side wall of the main conductive layer is lower than the surface of the main conductive layer.

13. The phase-changeable memory device of claim 12, wherein an end of the second barrier film extends downwards along the side wall of the main conductive layer.

14. The phase-changeable memory device of claim 9, wherein the main conductive layer formed from a tungsten metal film.

15. The phase-changeable memory device of claim 9, wherein the first and second barrier films are formed from a metallic nitride film.

16. A method of manufacturing a phase-changeable memory device, comprising:
forming an upper electrode on a top portion of a semiconductor substrate in which the semiconductor substrate includes a phase-change pattern;
forming an interlayer insulating layer over the upper electrode and over the semiconductor substrate;
forming a via-hole by etching the interlayer insulating layer to expose a top surface of the upper electrode;
forming a first barrier film on a bottom portion and on a side wall portion of the via-hole;
forming a main conductive layer to bury the via-hole;
flattening the main conductive layer and the first barrier film to expose the interlayer insulating layer;
forming a bit line contact unit by forming a second barrier film on the main conductive layer; and
forming a bit line on the bit line contact unit.

17. The method of claim 16, wherein in the flattening the main conductive layer and the first barrier film, a stepped portion is formed by excessively performing chemical and mechanical grinding such that the height of the main conductive layer is not level and is lower than that of the interlayer insulating layer.

18. The method of claim 17, further comprising selectively etching the first barrier film so that the first barrier film on a side wall of the via-hole is lower than the top of the main conductive layer wherein the selectively etching step is performed between the flattening step and the step of forming the second barrier film.

19. The method of claim 18, wherein the forming the bit line contact unit includes:
forming the second barrier film on the main conductive layer and the interlayer insulating layer so as to fill in the stepped portion; and
flattening the second barrier film so as to expose the interlayer insulating layer.

20. The method of claim 16, wherein the forming the bit line includes:
forming an insulating film on the interlayer insulating layer;
defining a bit line expected region by etching the insulating film to expose the bit line contact unit; and
burying a conductive layer in the bit line expected region.
